(19) United States
(12) Patent Application Publication
(10) Pub. No.: US 2024/0347504 A1
(43) Pub. Date: Oct. 17, 2024

(54) PHOTODIODE ARRAY AND METHOD FOR MANUFACTURING PHOTODIODE ARRAY

(71) Applicant: KYOCERA Corporation, Kyoto-shi, Kyoto (JP)

(72) Inventors: Genshitaro KAWAMURA, Kirishima-shi (JP); Naoyoshi KOMATSU, Tsukuba-shi (JP)

(73) Assignee: KYOCERA Corporation, Kyoto-shi, Kyoto (JP)

(21) Appl. No.: 18/292,529

(22) PCT Filed: Jul. 20, 2022
(86) PCT No.: PCT/JP2022/028242

§ 371 Date: Jan. 26, 2024

(30) Foreign Application Priority Data
Jul. 30, 2021 (JP) 2021-125809

(51) Int. Cl. H01L 25/04; H01L 31/02; H01L 31/0296; H01L 31/105

(52) U.S. Cl. CPC H01L 25/042; H01L 31/02005; H01L 31/0296; H01L 31/105

(57) ABSTRACT

A PIN semiconductor layer including Mg₂Si, a first electrode connected to a first surface of the PIN semiconductor layer, a support member being in contact with a surface of the first electrode via a connection layer, a second electrode and a third electrode which are connected to the PIN semiconductor layer on a second surface opposite to the first surface of the PIN semiconductor layer, and an ROIC structure connected to the second electrode and the third electrode are provided. The first electrode is disposed around a through groove, the second electrode is connected to a portion of the second surface where a p+ type semiconductor layer is located, the third electrode is connected to the first electrode and the through groove, the support member comprises a light-transmissive member having a lower coefficient of thermal expansion than Mg₂Si, and the connection layer includes an opening portion.

### TECHNICAL FIELD

The present disclosure relates to a photodiode array and a method for manufacturing a photodiode array.

### BACKGROUND OF INVENTION

A photodiode is known as an element that converts light into an electrical signal. Patent Document 1 discloses a photodiode using Mg₂Si.

### CITATION LIST

### Patent Literature

Patent Document 1: WO2019/187222

### SUMMARY

A photodiode array according to an aspect includes a PIN semiconductor layer including Mg₂Si and formed of an n+ type semiconductor layer, an n− type semiconductor layer, and a p+ type semiconductor layer; a first electrode connected to a first surface of the PIN semiconductor layer in which the n+ type semiconductor layer is formed; a support member being in contact with, via a connection layer, a surface of the first electrode opposite to a surface in contact with the first surface; a second electrode and a third electrode each connected on a second surface opposite to the first surface of the PIN semiconductor layer; and an ROIC structure connected to the second electrode and the third electrode. In the photodiode array, the first electrode is disposed around a through groove penetrating from the first surface to the second surface formed on the PIN semiconductor layer, the second electrode is connected to a portion of the second surface where the p+ type semiconductor layer is formed, the third electrode is connected to the first electrode and the through groove, the support member is made of a light-transmissive member having a lower coefficient of thermal expansion than Mg₂Si included in the PIN semiconductor layer, and the connection layer includes an opening portion through which light is transmitted to the PIN semiconductor layer via the support member.

A method for manufacturing a photodiode array according to an aspect includes forming a groove extending in a layering direction from a surface of a wafer of Mg₂Si serving as an n− type semiconductor layer of the PIN semiconductor layer including Mg₂Si and formed of an n+ type semiconductor layer, the n− type semiconductor layer, and a p+ type semiconductor layer, without penetrating the wafer of Mg₂Si; forming the n+ type semiconductor layer on a surface of the wafer in which the groove is formed; providing a first electrode connected to a first surface of the PIN semiconductor layer in which the n+ type semiconductor layer is formed; providing a support member in contact with, via a connection layer, a surface of the first electrode opposite to a surface in contact with the first surface; forming the n− type semiconductor layer by polishing the wafer until a distal end portion of the groove is exposed; forming the p+ type semiconductor layer in contact with a surface of the n− type semiconductor layer opposite to the first surface; providing a second electrode and a third electrode each connected on a second surface opposite to the first surface of the PIN semiconductor layer; and providing an ROIC structure connected to the second electrode and the third electrode. In the method for manufacturing a photodiode array, the first electrode is disposed around a through groove penetrating from the first surface to the second surface formed on the PIN semiconductor layer, the second electrode is connected to a portion of the second surface where the p+ type semiconductor layer is formed, the third electrode is connected to the first electrode and the through groove, the support member is made of a light-transmissive member having a lower coefficient of thermal expansion than Mg₂Si included in the PIN semiconductor layer, and the connection layer includes an opening portion through which light is transmitted to the PIN semiconductor layer via the support member.

### BRIEF DESCRIPTION OF THE DRAWINGS

FIG. 1 is a schematic cross-sectional view of a photodiode array according to a first embodiment.

FIG. 2 is a schematic view illustrating a process of manufacturing the photodiode array according to the first embodiment.

FIG. 3 is a schematic cross-sectional view of a first variation of the photodiode array according to the first embodiment.

FIG. 4 is a schematic cross-sectional view of a second variation of the photodiode array according to the first embodiment.

FIG. 5 is a schematic cross-sectional view of a photodiode array according to a second embodiment.

### DESCRIPTION OF EMBODIMENTS

The coefficient of thermal expansion of Mg₂Si is about five times that of Si. Therefore, when an Mg₂Si photodiode array and an ROIC structure, which is a readout circuit including Si, are connected to each other, a position shift may occur in a connecting portion due to a difference in the coefficient of thermal expansion. Accordingly, the reliability of the connecting portion in which the Mg₂Si photodiode array and the ROIC structure serving as the readout circuit are connected to each other needs to be improved.

A photodiode array and a method for manufacturing a photodiode array according to embodiments are described below.

### First Embodiment

### Photodiode Array

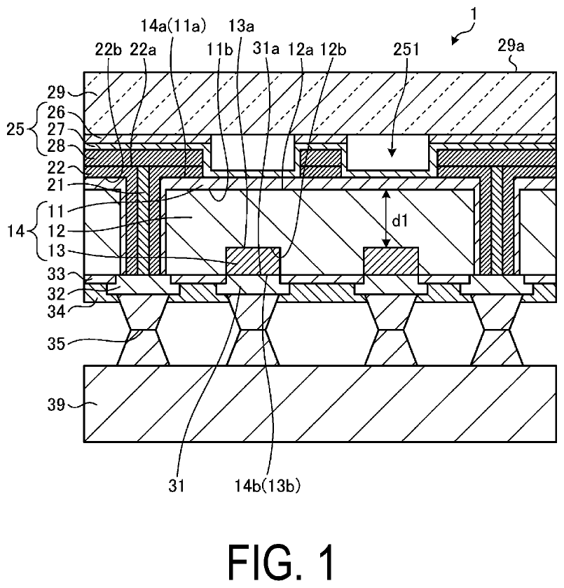

FIG. 1 is a schematic cross-sectional view of a photodiode array according to a first embodiment. In FIG. 1, a lower side corresponds to a front surface and an upper side corresponds to a back surface. A photodiode array 1 is a PIN photodiode. The photodiode array 1 uses Mg₂Si single crystal as a base member. The photodiode array 1 receives infrared light (infrared ray) IR from the back surface side and reflects the infrared light IR. The photodiode array 1 receives infrared light IR from an n-type layer on the side opposite to a p-type layer, and reflects the infrared light IR.

The infrared light IR has a wavelength in the range from 0.8 μm to 3.0 μm.

As illustrated in FIG. 1, the photodiode array 1 according to the embodiment includes a PIN semiconductor layer 14, first electrodes 22, a connection layer 25, a support member 29, second electrodes 31, third electrodes 32, and a read-out IC (ROIC) structure 39.

The PIN semiconductor layer 14 includes Mg₂Si, and is formed of an n+ type semiconductor layer 11, an n− type semiconductor layer 12, and a p+ type semiconductor layer 13. In the PIN semiconductor layer 14, the n+ type semiconductor layer 11, the n− type semiconductor layer 12, and the p+ type semiconductor layer 13 are layered. A first surface 14a of the PIN semiconductor layer 14 is an incident surface on which the infrared light IR is incident. The first surface 14a is a back surface side of the photodiode array 1. A second surface 14b is a surface opposite to the first surface 14a. The second surface 14b is a front surface side of the photodiode array 1.

The n+ type semiconductor layer 11 is an n+ type semiconductor layer. The n+ type semiconductor layer 11 includes Mg₂Si. The n+ type semiconductor layer 11 has a thickness in the layering direction in the range from 0.1 μm to 10 μm, for example. The thickness of the n+ type semiconductor layer 11 in the layering direction is preferably as thin as possible. The n+ type semiconductor layer 11 transmits infrared light. The n+ type semiconductor layer 11 has a surface 11a facing a surface 11b in contact with a surface 12a of the n− type semiconductor layer 12. The surface 11a is the first surface 14a of the PIN semiconductor layer 14. The n+ type semiconductor layer 11 is disposed around a through groove 21 so as to surround an outer periphery of the first electrode 22.

The n− type semiconductor layer 12 is in contact with the surface 11b of the n+ type semiconductor layer 11. The n− type semiconductor layer 12 is an I layer. The n− type semiconductor layer 12 is an n type semiconductor layer. The n− type semiconductor layer 12 includes Mg₂Si. The n− type semiconductor layer 12 has a thickness that allows absorption of infrared light. The n− type semiconductor layer 12 has a thickness d1 in the range from 100 μm to 500 μm, for example. The n− type semiconductor layer 12 has a surface 12b opposite to the surface 12a in contact with the surface 11b of the n+ type semiconductor layer 11.

The p+ type semiconductor layer 13 is a p+ type semiconductor layer. The p+ type semiconductor layer 13 includes Mg₂Si. The p+ type semiconductor layer 13 has a thickness in the range from 1 μm to 100 μm, for example. The p+ type semiconductor layer 13 has a surface 13a facing the surface 12b of the n− type semiconductor layer 12 and a surface 13b opposite to the surface 13a. The surface 13a of the p+ type semiconductor layer 13 forms a pn junction with the surface 12b of the n− type semiconductor layer 12. The surface 13b is the second surface 14b of the PIN semiconductor layer 14.

The through groove 21 penetrates from the first surface 14a to the second surface 14b formed on the PIN semiconductor layer 14. The through groove 21 may be filled with a material identical to that of a protective film 28 included in the connection layer 25. In the present embodiment, the through groove 21 is filled with the material identical to that of the protective film 28.

The first electrode 22 is connected to the first surface 14a of the PIN semiconductor layer 14 in which the n+ type semiconductor layer 11 is formed. The first electrode 22 is disposed around the through groove 21. The first electrode 22 extends along the layering direction of the PIN semiconductor layer 14. The first electrode 22 includes, for example, aluminum, or Cr and Au. The first electrode 22 is annularly disposed in a peripheral edge portion of the photodiode array 1. The first electrode 22 has a thickness in the range from 0.1 μm to 10 μm, for example.

The connection layer 25 connects the PIN semiconductor layer 14 with the support member 29. The connection layer 25 has a thickness in the range from 0.1 μm to 10 μm, for example. The connection layer 25 includes opening portions 251 through which light is transmitted to the PIN semiconductor layer 14 via the support member 29. The opening portions 251 is provided at a position overlapping the pn junction when viewed in the layering direction. The opening portion 251 is provided for each pixel unit. In the present embodiment, the connection layer 25 includes a metal film 26, an antireflection film 27, and the protective film 28.

The metal film 26 bonds the connection layer 25 and the support member 29 to each other. The metal film 26 is layered on the antireflection film 27. The metal film 26 is interposed between the antireflection film 27 and the support member 29. The metal film 26 has a thickness in the range from 0.1 μm to 10 μm, for example. The metal film 26 is made of, for example, aluminum. The metal film 26 is bonded to the support member 29 at room temperature.

The antireflection film 27 helps prevent reflection of infrared light on the incident surface of the photodiode array 1. The antireflection film 27 is interposed between the metal film 26 and the protective film 28. The antireflection film 27 transmits infrared light. The antireflection film 27 has a thickness in the range from 0.1 μm to 3 μm, for example. The antireflection film 27 is formed of, for example, about two or more and five or less dielectric layers in which a high refractive material such as TiO₂, Ta₂O₅, or ZrO₂ and a low refractive material such as SiO₂ or MgF₂ are combined.

The protective film 28 is interposed between the antireflection film 27 and the first electrode 22. The protective film 28 is made of, for example, SiO₂ or polyimide.

The support member 29 is in contact with a surface 22a, which is opposite to a surface 22b of the first electrode 22 in contact with the first surface 14a of the PIN semiconductor layer 14, via the connection layer 25. The support member 29 is disposed covering the entire surface of the PIN semiconductor layer 14 when viewed in the layering direction. In the present embodiment, the support member 29 is formed in a flat plate shape.

The support member 29 is formed using a light-transmissive member having a lower coefficient of thermal expansion than Mg₂Si included in the PIN semiconductor layer 14. The support member 29 transmits light. In the present embodiment, the support member 29 transmits infrared light. The support member 29 serves as a window member on the incident surface side of infrared light. The support member 29 is made of, for example, sapphire or silicon. The support member 29 preferably has a thickness of about 0.2 times to 2 times the thickness d1 of a PIN portion of the PIN semiconductor layer 14. The support member 29 is bonded to the metal film 26 of the connection layer 25 at room temperature.

The coefficient of thermal expansion of Mg₂Si is 13.1 ppm/° C. at 25° C. The coefficient of thermal expansion of silicon, which is a base member of the ROIC structure 39, is 2.6 ppm/° C. at 25° C. The coefficient of thermal expansion of the support member 29 is lower than 13.1 ppm/° C. at 25° C. The coefficient of thermal expansion of the support member 29 is preferably as close to that of the base member of the ROIC structure 39 as possible.

The second electrodes 31 and the third electrodes 32 are connected to the PIN semiconductor layer 14 on the second surface 14b opposite to the first surface 14a of the PIN semiconductor layer 14.

The second electrode 31 is connected to a portion of the second surface 14b where the p+ type semiconductor layer 13 is formed.

The third electrode 32 is connected to the first electrode 22 and the through groove 21. In the present embodiment, the third electrode 32 is connected to the protective film 28 included in the connection layer 25 via the material filling the through groove 21. In the present embodiment, the third electrode 32 is connected to an end portion of the n+ type semiconductor layer 11 in the layering direction.

The second electrode 31 and the third electrode 32 are disposed on an anode side of the photodiode array 1. The second electrode 31 and the third electrode 32 each include, for example, Ni and Au. The second electrode 31 and the third electrode 32 are disposed inward from an insulating film 34. The second electrode 31 has a thickness in the range from 0.1 μm to 10 μm, for example.

A surface protective film 33 is a protective layer that protects the surface of the photodiode array 1. The surface protective film 33 includes, for example, SiO₂. The surface protective film 33 is disposed at peripheral edge portions of the second electrode 31 and the third electrode 32. The surface protective film 33 is disposed inward from the insulating film 34. The surface protective film 33 has a thickness in the range from 0.1 μm to 10 μm, for example.

The insulating film 34 is an insulating layer that insulates the surface of the photodiode array 1. The insulating film 34 includes, for example, a solder resist. The insulating film 34 is disposed at the peripheral edge portions of the second electrode 31 and the third electrode 32. The insulating film 34 has a thickness in the range from 1 μm to 25 μm, for example.

The ROIC structure 39 is connected to the second electrodes 31 and the third electrodes 32 via bump bondings 35. The ROIC structure 39 is a circuit that extracts a current of the photodiode array 1. The ROIC structure 39 is disposed on the front surface side of the photodiode array 1. The base member of the ROIC structure 39 is silicon. The ROIC structure 39 is, for example, a voltage follower, a metal oxide semiconductor field effect transistor (MOSFET), or a MOS capacitor.

One bump bonding 35 is disposed for each of the second electrodes 31 and each of the third electrodes 32. A plurality of the bump bondings 35 are disposed in the photodiode array 1. The bump bondings 35 are in contact with the ROIC structure 39. In the present embodiment, pixels of the ROIC structure 39 and the photodiode array 1 are bonded with the bump bondings 35.

The infrared light IR is incident on the photodiode array 1 configured as described above from an n-type layer opposite to a p-type layer. The infrared light IR is incident on the back surface of the photodiode array 1.

### Reflection of Infrared Light

Reflection of the infrared light IR in the photodiode array 1 is described. The infrared light IR is incident from the back surface. The infrared light IR is incident from the opening portion 251 to the PIN semiconductor layer 14 via the support member 29. The infrared light IR passes through the n+ type semiconductor layer 11, the n− type semiconductor layer 12, and the p+ type semiconductor layer 13, and is reflected by a reflective surface 31a of the second electrode 31. Return light of the infrared light IR reflected by the reflective surface 31a of the second electrode 31 returns to the PIN semiconductor layer 14 side.

Since the photodiode array 1 is a PIN photodiode, the n− type semiconductor layer 12 as an I layer is depleted. Since the infrared light IR is incident from the back surface, the infrared light IR reaches the n− type semiconductor layer 12 as the I layer without the intervention of the p+ type semiconductor layer 13. The support member 29 and the antireflection film 27 transmit the infrared light IR. Thus, the infrared light IR reaches the n− type semiconductor layer 12 without being largely absorbed. Since the second electrode 31 and the ROIC structure 39 are disposed on the front surface side that is the p+ type semiconductor layer 13 side, the infrared light IR is not blocked before reaching the pn junction.

### Operation

The PIN semiconductor layer 14 is connected to the support member 29 through the connection layer 25. The support member 29 has a lower coefficient of thermal expansion than Mg₂Si included in the PIN semiconductor layer 14. Therefore, thermal expansion of the PIN semiconductor layer 14 is suppressed. Thus, a position shift in the bump bonding 35 is reduced.

The support member 29 is made of a light-transmissive member. Thus, even though the support member 29 is provided covering the entire surface of the PIN semiconductor layer 14, infrared light is transmitted through the support member 29 and enters the PIN semiconductor layer 14.

### Manufacturing Method

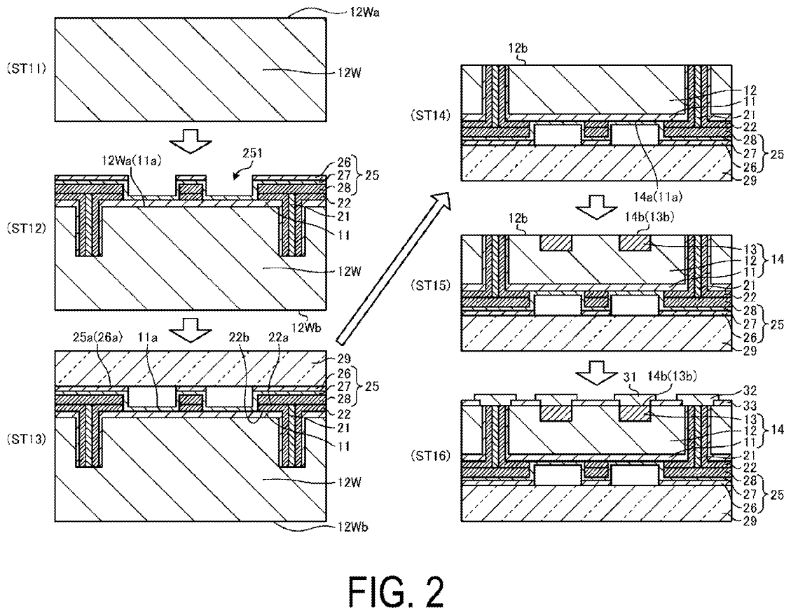

A process of manufacturing the photodiode array 1 is described with reference to FIG. 2. FIG. 2 is a schematic view illustrating a process of manufacturing the photodiode array according to the first embodiment.

First, a wafer 12W of Mg₂Si to be the n− type semiconductor layer 12 is prepared (step ST11). More specifically, step ST11 includes a step of preparing the wafer 12W of Mg₂Si which includes Mg₂Si and becomes the n− type semiconductor layer 12 of the PIN semiconductor layer 14 formed of the n+ type semiconductor layer 11, the n− type semiconductor layer 12, and the p+ type semiconductor layer 13. The wafer 12W has a plate shape. The wafer 12W has a larger thickness than the n− type semiconductor layer 12 of the PIN semiconductor layer 14 of the photodiode array 1 to be formed by polishing the wafer 12W in step ST14 described below.

After step ST11 is performed, the n+ type semiconductor layer 11 and the through grooves 21 are formed (step ST12). More specifically, step ST12 includes a step of forming the through grooves 21 extending in the layering direction from a surface 12Wa of the wafer 12W without penetrating the wafer 12W. The through grooves 21 extending from the surface 12Wa side of the wafer 12W toward a surface 12Wb are formed. The through grooves 21 have a depth large enough to penetrate the n− type semiconductor layer 12 of the PIN semiconductor layer 14 of the photodiode array 1 and not large enough to penetrate the wafer 12W. Step ST12 includes a step of forming the n+ type semiconductor layer 11 on the surface 12Wa of the wafer 12W in which the through grooves 21 are formed. The n+ type semiconductor layer 11 is layered on the surface 12Wa of the wafer 12W. Step ST12 includes a step of providing the first electrodes 22 connected to the first surface 14a of the PIN semiconductor layer 14 in which the n+ type semiconductor layer 11 is formed. The first electrode 22 is provided around the through groove 21. Subsequently, the connection layer 25 is provided.

After step ST12 is performed, the support member 29 is bonded onto the connection layer 25 (step ST13). More specifically, step ST13 includes a step of bonding the support member 29 in contact with, via the connection layer 25, the surface 22a of the first electrode 22 facing the surface 22b in contact with the first surface 14a of the PIN semiconductor layer 14. The support member 29 is bonded to a surface 26a of the metal film 26, which is a surface 25a of the connection layer 25. The support member 29 is bonded to the connection layer 25 at room temperature. The bonded support member 29 serves as a support substrate in steps subsequent to step ST14.

After step ST13 is performed, the wafer 12W is polished (step ST14). More specifically, after step ST13 is performed, the wafer 12W is turned upside down so that the surface 12Wb of the wafer 12W faces upward. The bonded support member 29 is used as a support substrate. Step ST14 includes a step of forming the n− type semiconductor layer 12 by polishing the wafer 12W until a distal end portion of the through groove 21 is exposed. The wafer 12W is polished from the surface 12Wb side of the wafer 12W so as to have the thickness of the n− type semiconductor layer 12. The distal end of the through groove 21 is exposed from the polished surface 12b of the n− type semiconductor layer 12.

After step ST14 is performed, the p+ type semiconductor layer 13 is formed (step ST15). More specifically, step ST15 includes a step of forming the p+ type semiconductor layer 13 in contact with the surface 12b of the n− type semiconductor layer 12 opposite to the first surface 14a. The p+ type semiconductor layer 13 is formed on the surface 12b side of the n− type semiconductor layer 12.

After step ST15 is performed, the second electrodes 31, the third electrodes 32, and the surface protective film 33 are formed (step S16). More specifically, step ST16 includes a step of providing the second electrodes 31 and the third electrodes 32 which are connected to the PIN semiconductor layer 14 on the second surface 14b opposite to the first surface 14a of the PIN semiconductor layer 14. On the surface 12b side of the n− type semiconductor layer 12, the second electrode 31 is connected to a portion where the p+ type semiconductor layer 13 is formed. The third electrode 32 is connected to the first electrode 22 and the through groove 21 on the surface 12b side of the n− type semiconductor layer 12. The surface protective film 33 is disposed at the peripheral edge portions of the second electrode 31 and the third electrode 32 on the surface 12b side of the n− type semiconductor layer 12.

Subsequently, a step of providing the ROIC structure 39 to be connected to the second electrodes 31 and the third electrodes 32 is performed. More specifically, the insulating film 34 is provided around the second electrodes 31 and the third electrodes 32, and the second electrodes 31 and the third electrodes 32 are connected to the ROIC structure 39 via the bump bondings 35. Thus, the photodiode array 1 is manufactured.

### Effects

In the present embodiment, the PIN semiconductor layer 14 is connected to the support member 29 via the connection layer 25. The support member 29 has a lower coefficient of thermal expansion than Mg₂Si included in the PIN semiconductor layer 14. According to the present embodiment, thermal expansion of the PIN semiconductor layer 14 can be suppressed. Thus, in the present embodiment, a position shift in the bump bonding 35 can be reduced. The present embodiment can improve the reliability of a connecting portion in which the photodiode array 1 of Mg₂Si and the ROIC structure 39, which is a readout circuit using Si as a base member, are connected to each other. The present embodiment can improve the reliability of the photodiode array 1.

In the present embodiment, the support member 29 is made of a light-transmissive member. According to the present embodiment, even though the support member 29 is provided covering the entire surface of the PIN semiconductor layer 14, infrared light can be transmitted through the support member 29 and enter the PIN semiconductor layer 14. In the present embodiment, an infrared light incident surface of the photodiode array 1 can be protected by the support member 29.

In the present embodiment, the support member 29 can be used as a support substrate when the photodiode array 1 is manufactured. According to the present embodiment, the photodiode array 1 can be stably and efficiently manufactured.

In the present embodiment, the support member 29 can be fixed at room temperature. According to the present embodiment, the support member 29 and the connection layer 25 can be bonded to each other without applying a thermal load. In the present embodiment, the reliability of the photodiode array 1 can be improved by reducing a position shift due to thermal expansion.

### First Variation

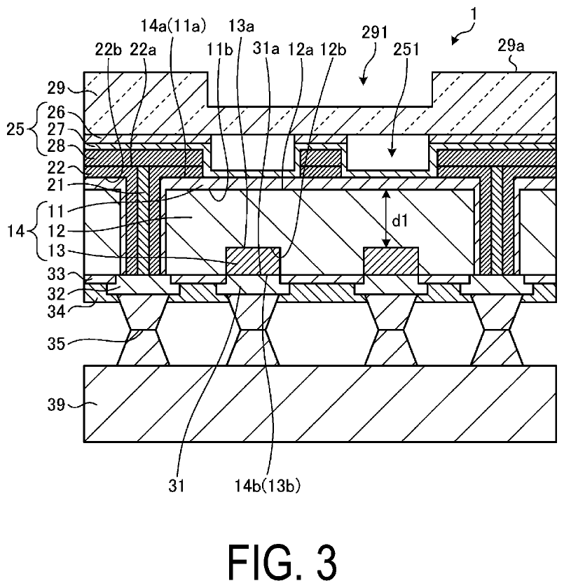

FIG. 3 is a schematic cross-sectional view of a first variation of the photodiode array according to the first embodiment. The photodiode array 1 is different from that of the first embodiment in the configuration of the support member 29. Constituent members common to those in the first embodiment are given the same reference signs and descriptions thereof are omitted. The same applies to the following description.

The support member 29 includes a recessed portion 291 in a surface 29a on a side opposite to a surface facing the connection layer 25. The support member 29 includes the recessed portion 291 on the surface 29a side. The recessed portion 291 is provided corresponding to the opening portions 251. In other words, the recessed portion 291 is provided at a position overlapping the opening portions 251 when viewed in the layering direction. The recessed portion 291 is recessed in a direction approaching the connection layer 25. In the recessed portion 291, the thickness of the support member 29 is thin.

The recessed portion 291 provided in such a configuration allows suppression of attenuation of infrared light in the support member 29.

### Second Variation

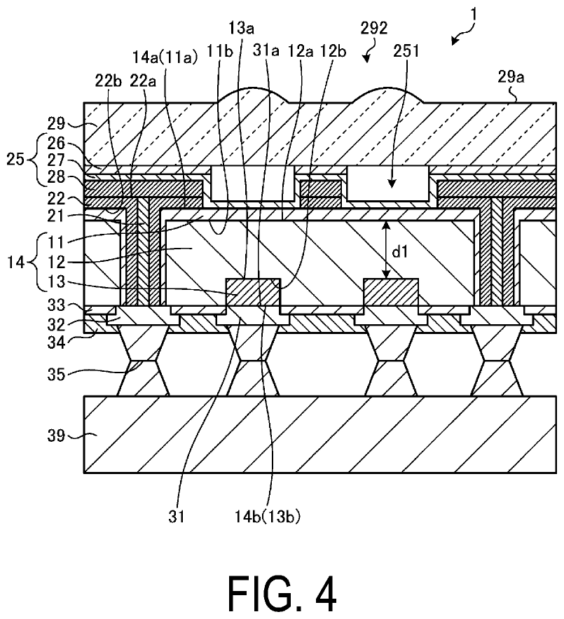

FIG. 4 is a schematic cross-sectional view of a second variation of the photodiode array according to the first embodiment. The photodiode array 1 is different from that of the first embodiment in the configuration of the support member 29.

The support member 29 includes a convex portion 292 on the surface 29a on the side opposite to the surface facing the connection layer 25. The support member 29 includes the convex portion 292 on the surface 29a side. The convex portion 292 includes, for example, a set of a plurality of convex portions 292, and is provided corresponding to the opening portions 251. In other words, each of the convex portions 292 is provided at a position overlapping a corresponding one of the opening portions 251 when viewed in the layering direction. The convex portion 292 protrudes in a spherical or aspherical shape in a direction away from the connection layer 25. In the convex portion 292, the thickness of the support member 29 is thick. Note that instead of forming the plurality of convex portions 292 as described above, a single convex portion 292 may be formed on the surface 29a so as to be provided at positions overlapping the plurality of opening portions 251.

In such a configuration, infrared light can be condensed at the convex portion 292 of the support member 29.

### Second Embodiment

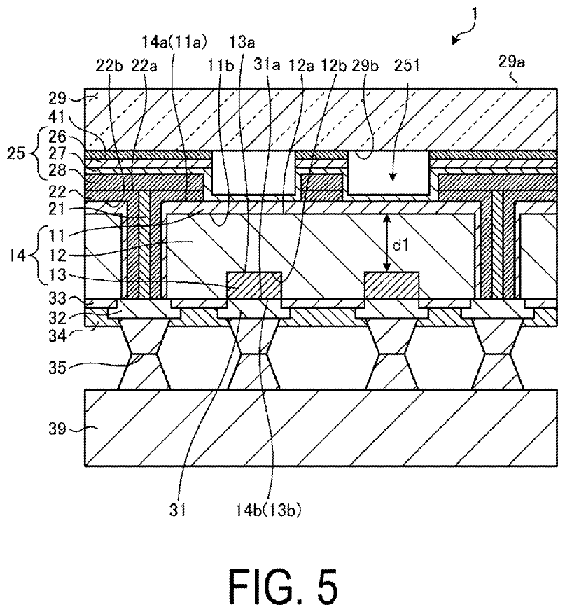

FIG. 5 is a schematic cross-sectional view of a photodiode array according to a second embodiment. The photodiode array 1 is different from that of the first embodiment in that a metal film 41 is provided.

The metal film 41 is provided on a surface 29b of the support member 29 facing the metal film 26 of the connection layer 25. The metal film 41 is interposed between the support member 29 and the metal film 26. The metal film 41 is provided corresponding to the position of the metal film 26. The metal film 41 is made of, for example, aluminum. The metal film 41 is bonded to the metal film 26 at room temperature.

According to the present embodiment, the support member 29 and the connection layer 25 can be more reliably bonded to each other without applying a thermal load. In the present embodiment, the reliability of the photodiode array 1 can be improved by reducing a position shift due to thermal expansion.

The embodiments disclosed in the present application can be modified without departing from the spirit and scope of the invention. The embodiments and variations thereof disclosed in the present application can be combined as appropriate.

Embodiments have been described in order to fully and clearly disclose the technique according to the appended claims. However, the appended claims are not to be limited to the embodiments described above and may be configured to embody all variations and alternative configurations that those skilled in the art may make within the underlying matter set forth herein.

### Others

The PIN semiconductor layer 14 may include a recessed portion in first surface 14a. More specifically, the recessed portions of the n+ type semiconductor layer 11 and the n− type semiconductor layer 12 are provided corresponding to the opening portions 251. In other words, the recessed portions of the n+ type semiconductor layer 11 and the n− type semiconductor layer 12 are provided at positions overlapping the opening portions 251 when viewed in the layering direction. In such a configuration, the thickness of the PIN semiconductor layer 14 can be optimized. Thus, efficient depletion can be achieved.

In the above-described embodiments, it is described that the connection layer 25 includes the metal film 26, the antireflection film 27, and the protective film 28; however, the antireflection film 27 and/or the protective film 28 need not be included. The metal film 26, the antireflection film 27, and the protective film 28 need not be provided, the first electrode 22 may be bonded to the metal film 41 of the support member 29 at room temperature, and the first electrode 22 may form the above-described metal film 26 and may also serve as the metal film 26.

### REFERENCE SIGNS

1 Photodiode array
11 n+ type semiconductor layer
12 n− type semiconductor layer
13 p+ type semiconductor layer
14 PIN semiconductor layer
14a First surface
14b Second surface
21 Through groove
22 First electrode
25 Connection layer
251 Opening portion
26 Metal film
27 Antireflection film
28 Protective film
29 Support member
31 Second electrode
32 Third electrode
33 Surface protective film
34 Insulating film
35 Bump bonding
39 ROIC structure

1. A photodiode array comprising:
a PIN semiconductor layer including Mg2Si, an n+ type semiconductor layer, an n− type semiconductor layer, and a p+ type semiconductor layer;
a first electrode connected to a first surface of the PIN semiconductor layer in which the n+ type semiconductor layer is located;
a support member being in contact with, via a connection layer, a surface of the first electrode opposite to a surface in contact with the first surface;
a second electrode and a third electrode which are connected to the PIN semiconductor layer on the second surface opposite to the first surface of the PIN semiconductor layer; and
an ROIC structure connected to the second electrode and the third electrode, wherein
the first electrode is disposed around a through groove penetrating from the first surface to the second surface located on the PIN semiconductor layer,
the second electrode is connected to a portion of the second surface where the p+ type semiconductor layer is located,
the third electrode is connected to the first electrode and the through groove,
the support member comprises a light-transmissive member having a lower coefficient of thermal expansion than Mg2Si included in the PIN semiconductor layer, and
the connection layer includes an opening portion through which light is transmitted to the PIN semiconductor layer via the support member.

2. The photodiode array according to claim 1, wherein the support member transmits infrared light.

3. The photodiode array according to claim 1, wherein the support member includes a recessed portion in a surface on a side opposite to a surface facing the connection layer.

4. The photodiode array according to claim 1, wherein the PIN semiconductor layer includes a recessed portion in the first surface.

5. The photodiode array according to claim 1, wherein the support member includes a convex portion on a surface on a side opposite to a surface facing the connection layer.

6. The photodiode array according to claim 1, wherein
the connection layer includes a metal film bonding the connection layer to the support member,
the metal film comprises aluminum,
the support member comprises sapphire or silicon, and
the metal film and the support member are bonded to each other at room temperature.

7. The photodiode array according to claim 1, wherein the connection layer includes a metal film bonding the connection layer to the support member, and
the metal film is located by the first electrode.

8. A method for manufacturing a photodiode array, the method comprising:
forming a groove extending in a layering direction from a surface of a wafer of Mg2Si serving as an n− type semiconductor layer of the PIN semiconductor layer including Mg2Si and formed of an n+ type semiconductor layer, the n− type semiconductor layer, and a p+ type semiconductor layer, without penetrating the wafer of Mg2Si;
forming the n+ type semiconductor layer on a surface of the wafer in which the groove is formed;
providing a first electrode connected to a first surface of the PIN semiconductor layer in which the n+ type semiconductor layer is formed;
bonding a support member in contact with, via a connection layer, a surface of the first electrode opposite to a surface in contact with the first surface;
forming the n− type semiconductor layer by polishing the wafer until a distal end portion of the groove is exposed;
forming the p+ type semiconductor layer in contact with a surface of the n− type semiconductor layer opposite to the first surface;
providing a second electrode and a third electrode which are connected to the PIN semiconductor layer on the second surface opposite to the first surface of the PIN semiconductor layer; and
providing an ROIC structure connected to the second electrode and the third electrode, wherein
the first electrode is disposed around a through groove penetrating from the first surface to the second surface formed on the PIN semiconductor layer,
the second electrode is connected to a portion of the second surface where the p+ type semiconductor layer is formed,
the third electrode is connected to the first electrode and the through groove,
the support member comprises a light-transmissive member having a lower coefficient of thermal expansion than Mg2Si included in the PIN semiconductor layer, and
the connection layer includes an opening portion through which light is transmitted to the PIN semiconductor layer via the support member.
